(19) United States
(12) Patent Application Publication
(10) Pub. No.: US 2026/0064150 A1
(43) Pub. Date: Mar. 5, 2026

(54) METHOD AND APPARATUS FOR PERFORMING DEVICE TYPE DETECTION OF MEMORY DEVICE WITH AID OF DRIVING VOLTAGE PATH DETECTION, AND ASSOCIATED COMPUTER-READABLE MEDIUM

(71) Applicant: Silicon Motion, Inc., Hsinchu County (TW)

(72) Inventors: Kuan-Fu Chen, Hsinchu County (TW); Chen-Hao Chen, Hsinchu County (TW)

(73) Assignee: Silicon Motion, Inc., Hsinchu County (TW)

(21) Appl. No.: 19/273,110

(22) Filed: Jul. 17, 2025

Related U.S. Application Data
(60) Provisional application No. 63/687,767, filed on Aug. 27, 2024.

(30) Foreign Application Priority Data
Jan. 21, 2025 (TW) 114102469

(51) Int. Cl. G05F 3/24; G01R 31/52

(52) U.S. Cl. CPC G05F 3/247; G01R 31/52

(57) ABSTRACT

A method for performing device type detection of a memory device with aid of driving voltage path detection and associated apparatus are provided, where the memory device is installed on a printed circuit board (PCB) of host device. The method includes: in response to a detection signal obtained from a driving voltage terminal of a set of driving voltage terminals among two sets of driving voltage terminals within the PCB, determining a device type of the memory device, for determining whether a memory device version of the memory device belongs to a first set of versions or a second set of versions; and selecting a voltage level corresponding to the device type from multiple predetermined voltage levels to be a selected voltage level, for providing the memory device with the selected voltage level via at least one portion of driving voltage terminals among the two sets of driving voltage terminals.

### CROSS REFERENCE TO RELATED APPLICATIONS

This application claims the benefit of U.S. Provisional Application No. 63/687,767, filed on August 27, 2024. The content of the application is incorporated herein by reference.

### BACKGROUND OF THE INVENTION

### 1. Field of the Invention

The present invention relates to memory control, and more particularly, to a method for performing device type detection of a memory device with aid of driving voltage path detection, and associated apparatus such as a host device, a printed circuit board (PCB) of the host device, an electronic device comprising the host device and the memory device, the memory device, a memory controller within the memory device, etc., as well as an associated computer-readable medium.

### 2. Description of the Prior Art

A memory device may comprise flash memory for storing data, and the management of accessing the flash memory is complicated. For example, the memory device may be a memory card, a solid state drive (SSD), or an embedded storage device such as that conforming to Universal Flash Storage (UFS) specification. The memory device may be arranged to store various files such as system files, user files, etc. in a file system of a host. Some problems may occur, however. When the hardware architecture of the host is designed to meet the needs of a certain version of UFS products, the hardware architecture may be incompatible with another version of UFS products. When the hardware architecture of the host is designed to meet the needs of the other version of UFS products, the hardware architecture may be incompatible with the aforementioned certain version of UFS products. The related art tries to correct the problems, but further problems such as some side effects may be introduced. Thus, a novel method and associated architecture are needed for solving the problems without introducing any side effect or in a way that is less likely to introduce a side effect.

### SUMMARY OF THE INVENTION

It is an objective of the present invention to provide a method for performing device type detection of a memory device with aid of driving voltage path detection, and associated apparatus such as a host device, a PCB of the host device, an electronic device comprising the host device and the memory device, the memory device, a memory controller within the memory device, etc., as well as an associated computer-readable medium, in order to solve the above-mentioned problems.

At least one embodiment of the present invention provides a method for performing device type detection of a memory device with aid of driving voltage path detection, where the memory device is installed on a PCB of a host device, for example, an electronic device may comprise the host device and the memory device, the memory device may comprise a memory controller and a non-volatile (NV) memory, and the NV memory may comprise at least one NV memory element (e.g., one or more NV memory elements). The method may comprise: in response to a detection signal obtained from a predetermined driving voltage terminal of a set of driving voltage terminals among two sets of driving voltage terminals within the PCB, determining a device type of the memory device, for determining whether a memory device version of the memory device belongs to a first set of versions (including one or more versions) or a second set of versions (including one or more other versions); and selecting a voltage level corresponding to the device type from multiple predetermined voltage levels to be a selected voltage level, for providing the memory device with the selected voltage level via at least one portion of driving voltage terminals among the two sets of driving voltage terminals. For example, the first set of versions may comprise the second version (or “the v2” for brevity) of the UFS specification, and the second set of versions may comprise multiple newer versions of the UFS specification, such as the third version (or “the v3” for brevity), the fourth version (or “the v4”for brevity), etc. of the UFS specification.

In addition to the above method, the present invention also provides a host device that operates according to the method mentioned above, and also provides a computer-readable medium storing a program code which causes the host device to operate according to the method mentioned above when executed by the host device. For example, the host device can determine the device type of the memory device, and provide the memory device with the selected voltage level via the aforementioned at least one portion of driving voltage terminals, in order to enhance the overall performance.

In addition to the above method, the present invention also provides a PCB for performing device type detection of a memory device with aid of driving voltage path detection, where the memory device is installed on the PCB of a host device. The PCB may comprise a control module and at least one power management integrated circuit (PMIC) (e.g., one or more PMICs) coupled to the control module. The control module may be arranged to control operations of the PCB, where the control module may comprise at least one circuit. In addition, the aforementioned at least one PMIC may be arranged to perform power management under control of the control module, for selectively providing at least one driving voltage to the memory device to be the power for the memory device. For example, in response to a detection signal obtained from a predetermined driving voltage terminal of a set of driving voltage terminals among two sets of driving voltage terminals within the PCB, the control module determines a device type of the memory device, for determining whether a memory device version of the memory device belongs to a first set of versions or a second set of versions; and the control module selects a voltage level corresponding to the device type from multiple predetermined voltage levels to be a selected voltage level, for providing the memory device with the selected voltage level via at least one portion of driving voltage terminals among the two sets of driving voltage terminals.

According to some embodiments, the apparatus may comprise at least one portion (e.g., a portion or all) of the electronic device. For example, the apparatus may comprise the host device within the electronic device. In another example, the apparatus may comprise the PCB of the host device. In yet another example, the apparatus may comprise the electronic device. In some examples, the apparatus may comprise the memory device and/or the memory controller within the memory device. In addition, the control module (or the aforementioned at least one circuit therein) may be implemented by way of a system on chip (SoC), a microcontroller/microcontroller unit (MCU), a PMIC, an automatic control circuit (e.g., a PMIC automatic control circuit for performing automatic control on the aforementioned at least one PMIC) within the PMIC, etc.

The method of the present invention and the associated apparatus can guarantee that the memory device can operate properly in various situations. More particularly, the hardware architecture of the host device can be compatible with any version among various versions (e.g., the v2, the v3 and the v4) of the UFS specification. For example, when the memory device version of the memory device belongs to the first set of versions (e.g., the v2) of the UFS specification, the hardware architecture of the host device can meet the needs of the first set of versions. In another example, when the memory device version of the memory device belongs to the second set of versions (e.g., the v3 and the v4) of the UFS specification, the hardware architecture of the host device can meet the needs of the second set of versions. In addition, the method of the present invention and the associated apparatus can solve the related art problems without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to an embodiment of the present invention.

FIG. 2 illustrates a first board system control scheme according to an embodiment of the present invention.

FIG. 3 illustrates a second board system control scheme according to an embodiment of the present invention.

FIG. 4 illustrates a universal board system control scheme of a method for performing device type detection of a memory device (e.g., a UFS device) with aid of driving voltage path detection according to an embodiment of the present invention.

FIG. 5 illustrates a first detection operation in a terminal reuse/redefinition control scheme of the method and a first sample under detection according to an embodiment of the present invention.

FIG. 6 illustrates a second detection operation in the terminal reuse/redefinition control scheme of the method and a second sample under detection according to an embodiment of the present invention.

FIG. 7 illustrates a first driving operation in a driving voltage control scheme of the method and the first sample using a set of driving voltages of the first driving operation according to an embodiment of the present invention.

FIG. 8 illustrates a second driving operation in the driving voltage control scheme of the method and the second sample using a set of driving voltages of the second driving operation according to an embodiment of the present invention.

FIG. 9 illustrates a working flow of the method according to an embodiment of the present invention.

### DETAILED DESCRIPTION

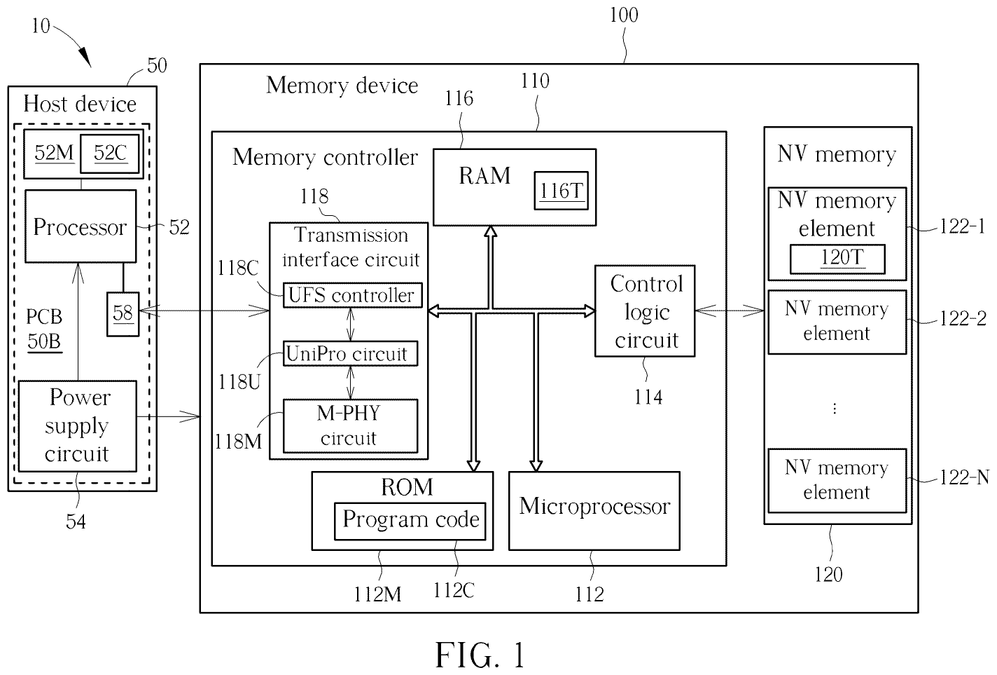

FIG. 1 is a diagram of an electronic device 10 according to an embodiment of the present invention, where the electronic device 10 may comprise a host device 50 and a memory device 100. The host device 50 may comprise at least one processor (e.g., one or more processors) which may be collectively referred to as the processor 52, a computer-readable medium 52M storing a program code 52C, a power supply circuit 54 as well as a transmission interface circuit 58, and may further comprise at least one PCB (e.g., one or more PCBs) which may be collectively referred to as the PCB 50B, where the processor 52 and the transmission interface circuit 58 may be coupled to each other through a bus. The processor 52 and the transmission interface circuit 58 may be coupled to the power supply circuit 54 to obtain power. One or more components of the host device 50, such as the processor 52, the computer-readable medium 52M, the power supply circuit 54 and the transmission interface circuit 58, may be installed on the PCB 50B of the host device 50. The processor 52 may be arranged to control operations of the host device 50, and the power supply circuit 54 may be arranged to provide the processor 52, the transmission interface circuit 58, and the memory device 100 with power, and output one or more driving voltages to the memory device 100, where the memory device 100 may provide the host device 50 with storage space, and may obtain the one or more driving voltages from the host device 50, to be the power for the memory device 100. Examples of the host device 50 may include, but are not limited to: a multifunctional mobile phone, a tablet computer, a wearable device, and a personal computer such as a desktop computer and a laptop computer. Examples of the memory device 100 may include, but are not limited to: a portable memory device (e.g., a memory card conforming to the SD/MMC, CF, MS or XD specification), a solid state drive (SSD), and various types of embedded memory devices (e.g., an embedded memory device conforming to the UFS or eMMC specification). In addition, the computer-readable medium 52M may be implemented by way of one or more hard disk drives (HDDs), one or more SSDs, etc. According to this embodiment, the memory device 100 may comprise a controller such as a memory controller 110, and may further comprise a non-volatile (NV) memory 120, where the controller is arranged to access the NV memory 120, and the NV memory 120 is arranged to store information. The NV memory 120 may comprise at least one NV memory element (e.g., one or more NV memory elements), such as a plurality of NV memory elements 122-1, 122-2, . . . , and 122-N, where “N” may represent a positive integer that is greater than one. For example, the NV memory 120 may be a flash memory, and the plurality of NV memory elements 122-1, 122-2, . . . , and 122-N may be a plurality of flash memory chips or a plurality of flash memory dies, respectively, but the present invention is not limited thereto.

As shown in FIG. 1, the memory controller 110 may comprise a processing circuit such as a microprocessor 112, a storage unit such as a read only memory (ROM) 112M, a control logic circuit 114, a Random Access Memory (RAM) 116 (which may be implemented by way of Static Random Access Memory (SRAM), for example), and a transmission interface circuit 118, where at least one portion (e.g., a portion or all) of the above components may be coupled to one another via a bus. The RAM 116 may be arranged to provide the memory controller 110 with internal storage space (for example, may temporarily store information), but the present invention is not limited thereto. In addition, the ROM 112M of this embodiment is arranged to store a program code 112C, and the microprocessor 112 is arranged to execute the program code 112C to control access to the NV memory 120. It should be noted that, the program code 112C may also be stored in the RAM 116 or any type of memory. Additionally, the control logic circuit 114 may be arranged to control the NV memory 120. The control logic circuit 114 may comprise an error correction code (ECC) circuit (not shown in FIG. 1), which may perform ECC encoding and ECC decoding, to protect data, and/or perform error correction, and the transmission interface circuit 118 may comprise multiple sub-circuits, which may interact with each other to perform communications. The transmission interface circuit 118 may conform to one or more communications specifications among various communications specifications (e.g., the Serial Advanced Technology Attachment (SATA) specification, the Universal Serial Bus (USB) specification, the Peripheral Component Interconnect Express (PCIe) specification, the embedded Multi Media Card (eMMC) specification, and the Universal Flash Storage (UFS) specification), and may perform communications with the host device 50 (or the transmission interface circuit 58 therein) according to the one or more communications specifications for the memory device 100. Similarly, the transmission interface circuit 58 may conform to the one or more communications specifications, and may perform communications with the memory device 100 (or the transmission interface circuit 118 therein) according to the one or more communications specifications for the host device 50. For example, the multiple sub-circuits of the transmission interface circuit 118 may comprise a UFS controller 118C, a Unified Protocol (UniPro) circuit 118U and a physical layer (PHY) circuit such as a Mobile Industry Processor Interface (MIPI) M-PHY circuit 118M (labeled “M-PHY circuit” for brevity), and the transmission interface circuit 58 may be implemented to have a circuitry architecture (e.g., multiple corresponding sub-circuits) similar to or the same as that of the transmission interface circuit 118, but the present invention is not limited thereto.

In this embodiment, the host device 50 may transmit a plurality of host commands and corresponding logical addresses to the memory controller 110, to access the NV memory 120 within the memory device 100, indirectly. The memory controller 110 receives the plurality of host commands and the logical addresses, and translates the plurality of host commands into memory operating commands (which may be referred to as operating commands, for brevity), respectively, and further controls the NV memory 120 with the operating commands to perform reading or writing/programming upon the memory units or data pages of specific physical addresses within the NV memory 120, where the physical addresses can be associated with the logical addresses. For example, the memory controller 110 may generate or update at least one logical-to-physical (L2P) address mapping table to manage the relationships between the physical addresses and the logical addresses. The NV memory 120 may store a global L2P address mapping table 120T, for the memory controller 110 to control the memory device 100 to access data in the NV memory 120, but the present invention is not limited thereto.

For better comprehension, the global L2P address mapping table 120T may be located in a predetermined region within the NV memory element 122-1, such as a system region, but the present invention is not limited thereto. For example, the global L2P address mapping table 120T may be divided into a plurality of local L2P address mapping tables, and the local L2P address mapping tables may be stored in one or more of the NV memory elements 122-1, 122-2, . . . , and 122-N, and more particularly, may be stored in the NV memory elements 122-1, 122-2, . . . , and 122-N, respectively. When there is a need, the memory controller 110 may load at least one portion (e.g., a portion or all) of the global L2P address mapping table 120T into the RAM 116 or other memories. For example, the memory controller 110 may load a local L2P address mapping table among the plurality of local L2P address mapping tables into the RAM 116 to be a temporary L2P address mapping table 116T, for accessing data in the NV memory 120 according to the local L2P address mapping table which is stored as the temporary L2P address mapping table 116T, but the present invention is not limited thereto.

In addition, the aforementioned at least one NV memory element (e.g., the one or more NV memory elements such as the NV memory elements {122-1, 122-2, . . . , 122-N}) may comprise a plurality of blocks, where the minimum unit that the memory controller 110 may perform operations of erasing data on the NV memory 120 may be a block, and the minimum unit that the memory controller 110 may perform operations of writing data on the NV memory 120 may be a page, but the present invention is not limited thereto. For example, any NV memory element 122-n (where “n” may represent any integer in the interval [1, N]) among the NV memory elements 122-1, 122-2, . . . , and 122-N may comprise multiple blocks, and a block within the multiple blocks may comprise and record a specific number of pages, where the memory controller 110 may access a certain page of a certain block within the multiple blocks according to a block address and a page address.

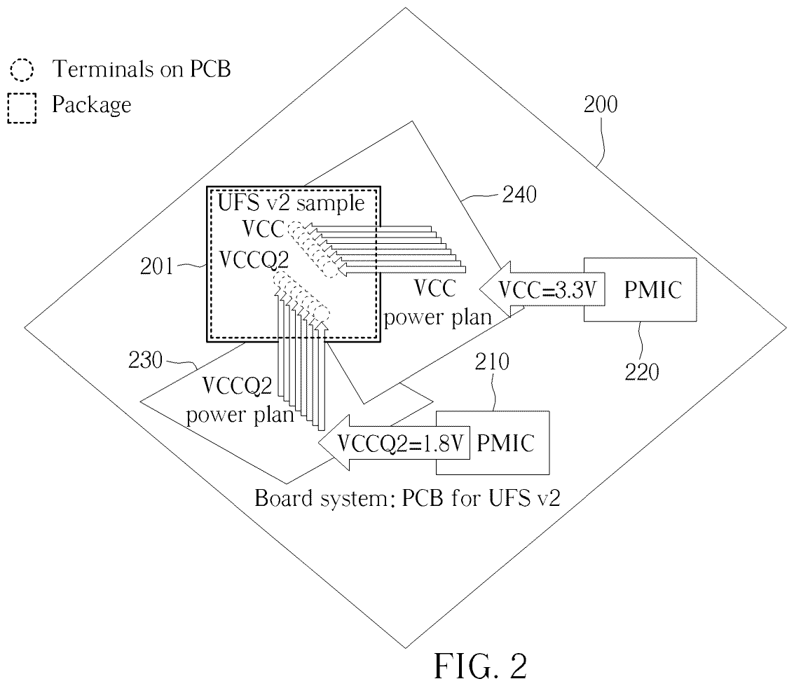

FIG. 2 illustrates a first board system control scheme according to an embodiment of the present invention, where a board system such as the PCB 200 corresponding to the first board system control scheme may support any memory device 100 conforming to the second version (or “the v2”) of the UFS specification, such as a UFS v2 sample with the package thereof (labeled “Board system: PCB for UFS v2” for brevity), and may be taken as an example of the PCB 50B shown in FIG. 1. The PCB 200 may comprise at least one PMIC (e.g., one or more PMICs) such as the PMICs 210 and 220 for generating multiple driving voltages VCCQ2 and VCC, and may output the multiple driving voltages VCCQ2 and VCC via multiple sets of terminals on the PCB 200 for the multiple driving voltages VCCQ2 and VCC, respectively. Among the multiple sets of terminals for outputting the multiple driving voltages VCCQ2 and VCC, the set of terminals for outputting the driving voltage VCCQ2 may be referred to as the VCCQ2 terminals, and the set of terminals for outputting the driving voltage VCC may be referred to as the VCC terminals. In addition, the PMICs 210 and 220 may be configured for providing the driving voltages VCCQ2 and VCC to the UFS v2 sample installed at an installation region 201 on the PCB 200 via the VCCQ2 power plan 230 and the VCC power plan 240 (e.g., the power plans 230 and 240 equipped with the power delivery sub-circuits for the driving voltages VCCQ2 and VCC, respectively) and the associated terminals (e.g., the VCCQ2 terminals and the VCC terminals in accordance with the ball out of the v2 of the UFS specification) on the PCB 200, respectively, where the voltage levels of the driving voltages VCCQ2 and VCC may be equal to the voltage levels of 1.8 volts (V) and 3.3 V, respectively.

When the hardware architecture on the PCB 50B (e.g., the PCB 200) of the host device 50 is designed to meet the needs of a predetermined version of UFS products, such as the UFS v2 sample, the hardware architecture may be incompatible with at least one other version of UFS products, such as UFS products conforming to the subsequent versions of the UFS specification.

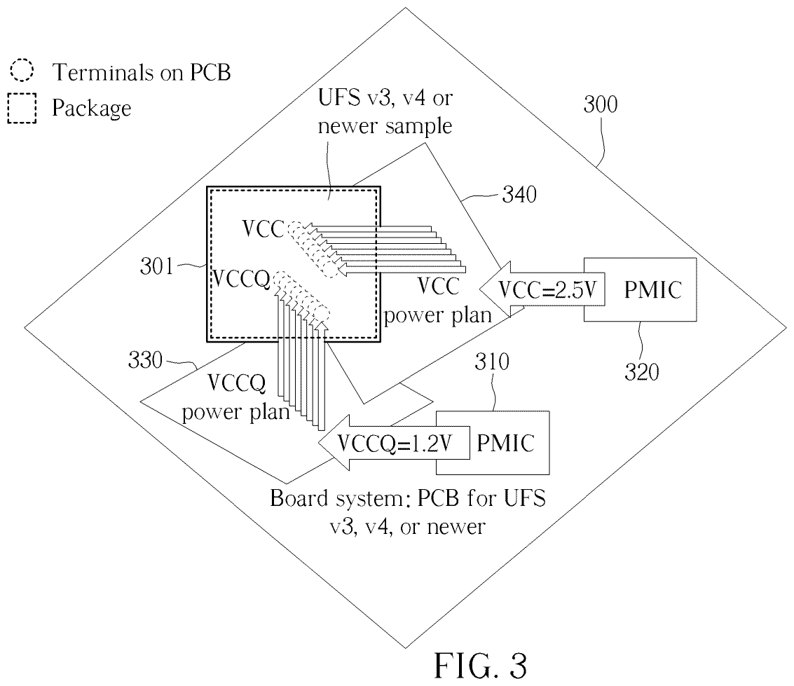

FIG. 3 illustrates a second board system control scheme according to an embodiment of the present invention, where a board system such as the PCB 300 corresponding to the second board system control scheme may support any memory device 100 conforming to the third version (or “the v3”), the fourth version (or “the v4”) or at least one newer and/or subsequent version (or “the newer version”) of the UFS specification, such as a UFS sample of the v3, the v4 or the newer version (or “the UFS v3, v4 or newer sample”) with the package thereof (labeled “Board system: PCB for UFS v3, v4, or newer” for brevity), and may be taken as an example of the PCB 50B shown in FIG. 1. The PCB 300 may comprise at least one PMIC (e.g., one or more PMICs) such as the PMICs 310 and 320 for generating multiple driving voltages VCCQ and VCC, and may output the multiple driving voltages VCCQ and VCC via multiple sets of terminals on the PCB 300 for the multiple driving voltages VCCQ and VCC, respectively. Among the multiple sets of terminals for outputting the multiple driving voltages VCCQ and VCC, the set of terminals for outputting the driving voltage VCCQ may be referred to as the VCCQ terminals, and the set of terminals for outputting the driving voltage VCC may be referred to as the VCC terminals. In addition, the PMICs 310 and 320 may be configured for providing the driving voltages VCCQ and VCC to the UFS v3, v4 or newer sample installed at an installation region 301 on the PCB 300 via the VCCQ power plan 330 and the VCC power plan 340 (e.g., the power plans 330 and 340 equipped with the power delivery sub-circuits for the driving voltages VCCQ and VCC, respectively) and the associated terminals (e.g., the VCCQ terminals and the VCC terminals in accordance with the ball out of the v3, the v4 or the newer version of the UFS specification) on the PCB 300, respectively, where the voltage levels of the driving voltages VCCQ and VCC may be equal to the voltage levels of 1.2 V and 2.5 V, respectively.

When the hardware architecture on the PCB 50B (e.g., the PCB 300) of the host device 50 is designed to meet the needs of another predetermined version of UFS products, such as the UFS v3, v4 or newer sample, the hardware architecture may be incompatible with at least one other version of UFS products, such as UFS products conforming to the v2 of the UFS specification.

As the circuit board layout typically needs special designs for the UFS v2 sample and the UFS v3, v4 or newer sample, respectively, the PCB design of the PCB 50B (e.g., the PCB 200 or the PCB 300) as well as the bill of materials (BOM) may vary in response to different requirements of ball out, etc., causing the associated costs such as the material costs, the labor costs, etc. to be increased. According to some embodiments, the electronic device 10 (or the host device 50 and/or the memory device 100 therein) may operate according to a method for performing device type detection of the memory device 100 (e.g., a UFS device) with the aid of driving voltage path detection, in order to improve the overall performance. In response to a detection signal (e.g., a UFS version detection signal UFS_VERSION_DETECTION) obtained from a predetermined driving voltage terminal such as a driving voltage terminal of a set of driving voltage terminals among two sets of driving voltage terminals (e.g., a set of VCCQ terminals and a set of VCCQ2 terminals), a control module on the PCB 50B may determine a device type of the memory device 100 for determining whether the memory device version of the memory device 100 (e.g., the UFS device) belongs to a first set of versions or a second set of versions, and select a voltage level corresponding to the device type from multiple predetermined voltage levels to be a selected voltage level, for providing the memory device 100 with the selected voltage level via at least one portion of driving voltage terminals (e.g., a portion of driving voltage terminals or all driving voltage terminals) among the two sets of driving voltage terminals. For example, the first set of versions may comprise the second version (v2) of the UFS specification, and the second set of versions may comprise newer versions of the UFS specification, such as the third version (v3), the fourth version (v4), etc. of the UFS specification.

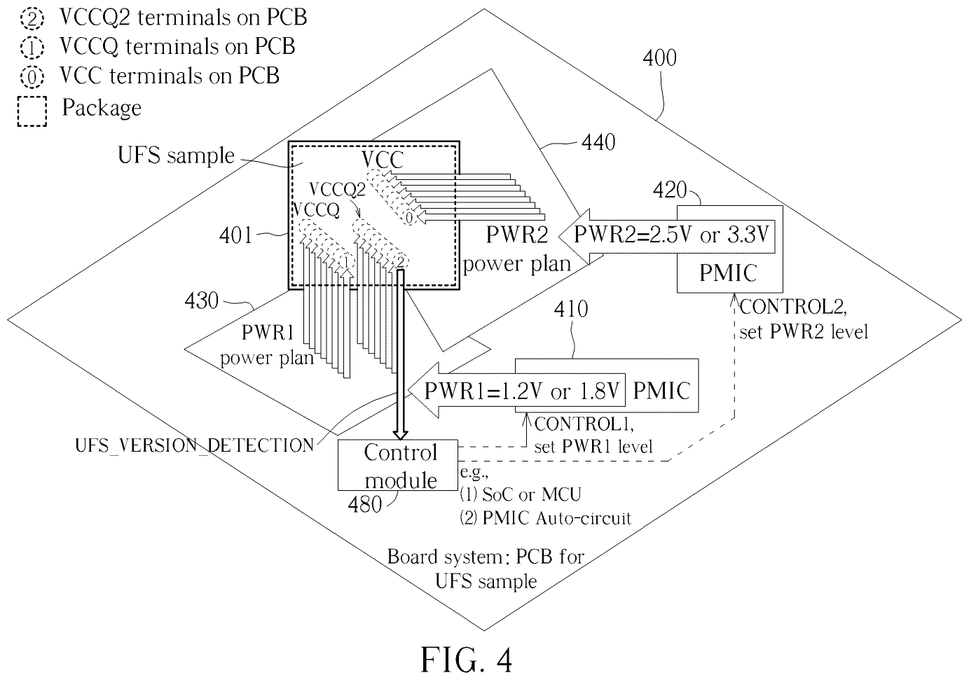

FIG. 4 illustrates a universal board system control scheme of the method according to an embodiment of the present invention, where a board system such as the PCB 400 corresponding to the universal board system control scheme may support any memory device 100 conforming to any version among various versions (e.g., the v2, the v3, the v4 and the newer version) of the UFS specification, such as a UFS sample of the v2, the v3, the v4 or the newer version with the package thereof (labeled “Board system: PCB for UFS sample” for brevity), and may be taken as an example of the PCB 50B shown in FIG. 1. The PCB 400 may comprise at least one PMIC (e.g., one or more PMICs) such as the PMICs 410 and 420. In particular, multiple predetermined configurations of the host device 50 may comprise a first predetermined configuration and a second predetermined configuration. The multiple predetermined configurations may also be regarded as the predetermined configurations of the PCB 50B therein such as the PCB 400. Taking the control module 480 as an example of the aforementioned control module, the associated operations in the first predetermined configuration and the second predetermined configuration may be described as follows.

In the first predetermined configuration, under the control of the control module 480, the PMICs 410 and 420 may be configured to provide the driving voltages PWR1 and PWR2 to a UFS v2 sample such as that mentioned above. This UFS v2 sample is installed at an installation region 401 on the PCB 400. The driving voltages PWR1 and PWR2 are supplied via the PWR1 power plan 430, the PWR2 power plan 440, and their associated terminals on the PCB 400. The driving voltages PWR1 and PWR2 act as the driving voltages VCCQ2 and VCC, respectively. The PWR1 power plan 430 and the PWR2 power plan 440 act as the VCCQ2 power plan 230 and the VCC power plan 240, respectively. The associated terminals are the VCCQ2 terminals and the VCC terminals, in accordance with the ball out of the v2 of the UFS specification. The voltage levels for the driving voltages VCCQ2 and VCC are equal to 1.8 V and 3.3 V, respectively.

In the second predetermined configuration, under the control of the control module 480, the PMICs 410 and 420 may be configured to provide the driving voltages PWR1 and PWR2 to a UFS v3, v4 or newer sample such as that mentioned above. This UFS v3, v4 or newer sample is installed at the installation region 401 on the PCB 400. The driving voltages PWR1 and PWR2 are supplied via the PWR1 power plan 430, the PWR2 power plan 440, and their associated terminals on the PCB 400. The driving voltages PWR1 and PWR2 act as the driving voltages VCCQ and VCC, respectively. The PWR1 power plan 430 and the PWR2 power plan 440 act as the VCCQ power plan 330 and the VCC power plan 340, respectively. The associated terminals are the VCCQ terminals and the VCC terminals, in accordance with the ball out of the v3, the v4 or the newer version of the UFS specification. The voltage levels for the driving voltages VCCQ and VCC are equal to 1.2 V and 2.5 V, respectively.

In the above embodiments, the aforementioned control module such as the control module 480 may be implemented in various manners. For example, the control module 480 may be implemented by way of SoC, MCU, etc., in particular, using a program module such as a software module or a firmware module running on a processor/microprocessor. In another example, the control module 480 may be implemented by way of PMIC automatic control circuit (labeled “PMIC Auto-circuit” for brevity), etc., in particular, using a hardware circuit comprising logic circuits, etc. for automatic control.

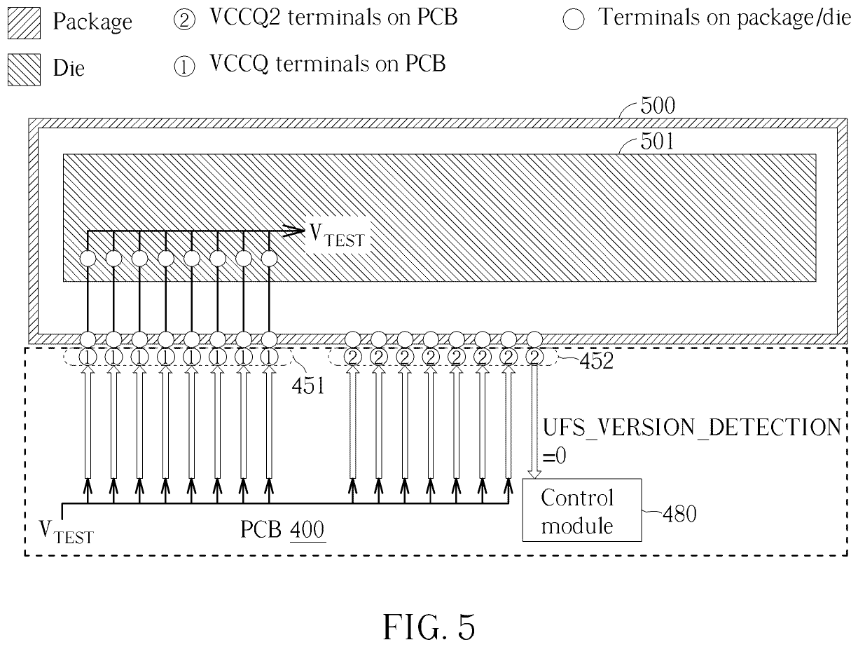

FIG. 5 illustrates a first detection operation in a terminal reuse/redefinition control scheme of the method and a first sample under detection according to an embodiment of the present invention, where the control module 480 may utilize any PMIC of the power supply circuit 54 shown in FIG. 1, such as a predetermined PMIC among the PMICs 410 and 420 within the power supply circuit 54, to generate a testing voltage V_{TEST} in a testing phase among multiple phases of the host device 50 (or the control module 480 therein), for testing the memory device 100 such as the first sample. For example, the first sample may represent the UFS sample shown in the upper half part of FIG. 5, such as at least one die (e.g., one or more dies) which may be collectively referred to as the die 501 as well as the package 500 thereof. The control module 480 may utilize the PMIC 410 to generate the driving voltage VCCQ with VCCQ=1.2 V to be the testing voltage V_{TEST} in the first detection operation, but the present invention is not limited thereto. In some examples, as long as the implementation of the present invention will not be hindered and no malfunction of the electronic device 10 (or the host device 50 and/or the memory device 100 therein) will occur, the control module 480 may utilize any of the aforementioned PMICs to generate any voltage PWR of any voltage level to be the testing voltage V_{TEST} in the first detection operation.

As shown in the lower half part of FIG. 5, all terminals among the set of VCCQ terminals 451 and most terminals among the set of VCCQ2 terminals 452, except a predetermined terminal among the set of VCCQ2 terminals 452, may be coupled to the testing voltage V_{TEST}. When the first sample such as the die 501 with the package 500 thereof is mounted on the PCB 400, the set of VCCQ terminals 451 and the set of VCCQ2 terminals 452 are coupled to the associated terminals on the package 500, such as the terminals in accordance with the ball out of any version (e.g., the v2, the v3, the v4 or the newer version) of the UFS specification. Typically, the wire bonding of the die 501 regarding the driving voltages VCCQ and VCCQ2 may be involved with only one driving voltage among the driving voltages VCCQ and VCCQ2, in order to save the associated costs such as the material costs, the time costs, etc. As a result, the driving voltage connection paths corresponding to the aforementioned only one driving voltage among the driving voltages VCCQ and VCCQ2 will be valid, while the driving voltage connection paths corresponding to the other driving voltage among the driving voltages VCCQ and VCCQ2 will be invalid, causing the voltage level of the UFS version detection signal UFS_VERSION_DETECTION to be equal to zero (0). Therefore, in the testing phase, the control module 480 may classify the memory device 100 such as the first sample (or the die 501 packed in the package 500 thereof) according to the UFS version detection signal UFS_VERSION_DETECTION (e.g., UFS_VERSION_DETECTION=0) to determine the device type of the memory device 100, and more particularly, determine whether the first sample belongs to the UFS v2 samples or the UFS v3, v4 or newer version samples.

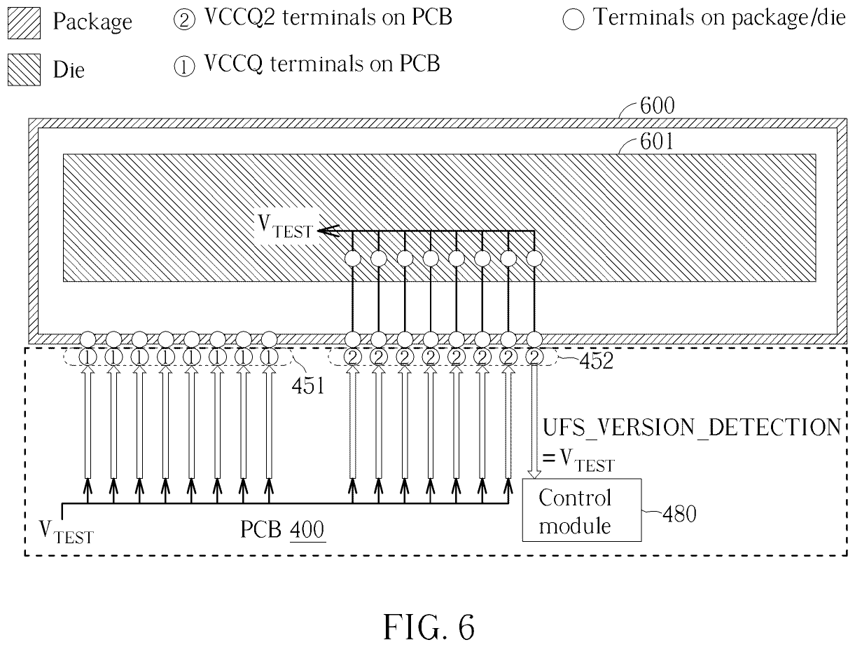

FIG. 6 illustrates a second detection operation in the terminal reuse/redefinition control scheme of the method and a second sample under detection according to an embodiment of the present invention, where the control module 480 may utilize any of the aforementioned PMICs of the power supply circuit 54 shown in FIG. 1, such as the predetermined PMIC among the PMICs 410 and 420 within the power supply circuit 54, to generate the testing voltage V_{TEST} in the testing phase among the multiple phases of the host device 50 (or the control module 480 therein), for testing the memory device 100 such as the second sample. For example, the second sample may represent the UFS sample shown in the upper half part of FIG. 6, such as at least one die (e.g., one or more dies) which may be collectively referred to as the die 601 as well as the package 600 thereof. The control module 480 may utilize the PMIC 410 to generate the driving voltage VCCQ with VCCQ=1.2 V to be the testing voltage V_{TEST} in the second detection operation, but the present invention is not limited thereto. In some examples, as long as the implementation of the present invention will not be hindered and no malfunction of the electronic device 10 (or the host device 50 and/or the memory device 100 therein) will occur, the control module 480 may utilize any of the aforementioned PMICs to generate any of the aforementioned voltages PWR of any of the aforementioned voltage levels as the testing voltage V_{TEST} in the second detection operation.

As shown in the lower half part of FIG. 6, all terminals among the set of VCCQ terminals 451 and most terminals among the set of VCCQ2 terminals 452, except the predetermined terminal among the set of VCCQ2 terminals 452, may be coupled to the testing voltage V_{TEST}. When the second sample such as the die 601 with the package 600 thereof is mounted on the PCB 400, the set of VCCQ terminals 451 and the set of VCCQ2 terminals 452 are coupled to the associated terminals on the package 600, such as the terminals in accordance with the ball out of any of the aforementioned versions (e.g., the v2, the v3, the v4 or the newer version) of the UFS specification. Typically, the wire bonding of the die 601 regarding the driving voltages VCCQ and VCCQ2 may be involved with only one driving voltage among the driving voltages VCCQ and VCCQ2, in order to save the associated costs such as the material costs, the time costs, etc. As a result, the driving voltage connection paths corresponding to the aforementioned only one driving voltage among the driving voltages VCCQ and VCCQ2 will be valid, while the driving voltage connection paths corresponding to the other driving voltage among the driving voltages VCCQ and VCCQ2 will be invalid, causing the voltage level of the UFS version detection signal UFS_VERSION_DETECTION to be equal to the testing voltage V_{TEST}. Therefore, in the testing phase, the control module 480 may classify the memory device 100 such as the second sample (or the die 601 packed in the package 600 thereof) according to the UFS version detection signal UFS_VERSION_DETECTION (e.g., UFS_VERSION_DETECTION=V_{TEST}) to determine the device type of the memory device 100, and more particularly, determine whether the second sample belongs to the UFS v2 samples or the UFS v3, v4 or newer version samples.

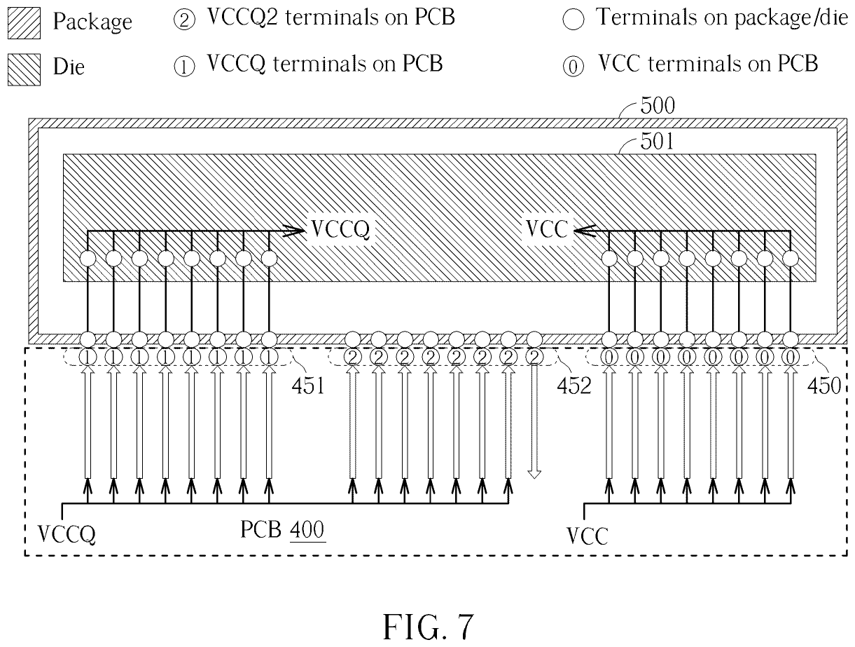

FIG. 7 illustrates a first driving operation in a driving voltage control scheme of the method and the first sample using a set of driving voltages of the first driving operation according to an embodiment of the present invention. In a driving phase among the multiple phases of the host device 50, the control module 480 may set the respective state (or the respective logical values) of the control signals CONTROL1 and CONTROL2 according to the classification result of the first sample, and control the PMICs 410 and 420 with the control signals CONTROL1 and CONTROL2 to set the driving voltages PWR1 and PWR2, respectively, where the UFS version detection signal UFS_VERSION_DETECTION (e.g., UFS_VERSION_DETECTION=0) may indicate the classification result of the first sample, such as the classification result of whether the first sample belongs to the UFS v2 samples or the UFS v3, v4 or newer version samples, so the control module 480 may set the respective state (or the respective logical values) of the control signals CONTROL1 and CONTROL2 according to the UFS version detection signal UFS_VERSION_DETECTION, to provide the driving voltages corresponding to the classification result.

When UFS_VERSION_DETECTION=0, indicating that the first sample belongs to the UFS v3, v4 or newer version samples, the control module 480 may set the respective state of the control signals CONTROL1 and CONTROL2 according to the UFS version detection signal UFS_VERSION_DETECTION in order to set the voltage level of the driving voltage PWR1 (or “the PWR1 level”) and the voltage level of the driving voltage PWR2 (or “the PWR2 level”), respectively, for controlling the PMICs 410 and 420 to provide the driving voltages VCCQ and VCC corresponding to the classification result, where VCCQ=1.2 V and VCC=2.5 V.

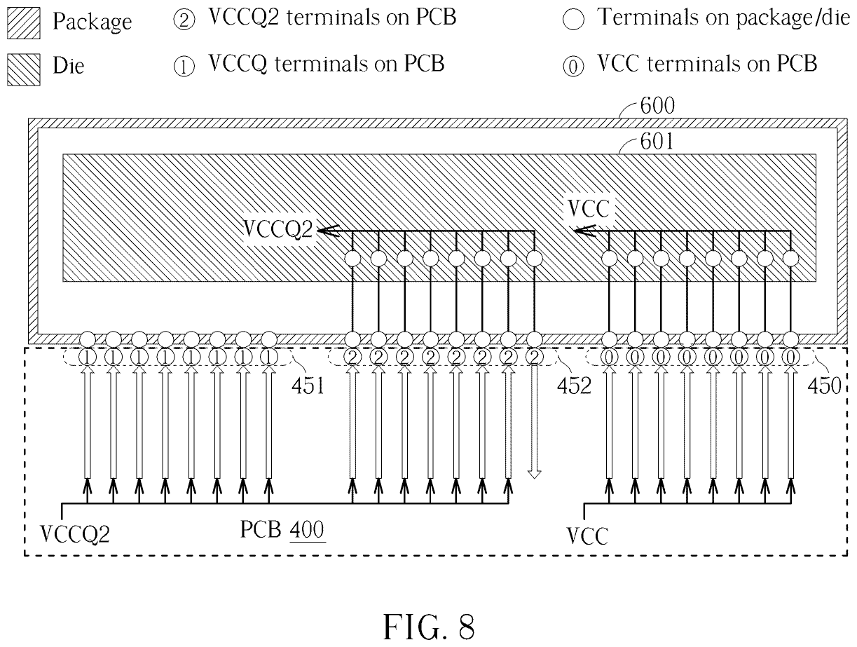

FIG. 8 illustrates a second driving operation in the driving voltage control scheme of the method and the second sample using a set of driving voltages of the second driving operation according to an embodiment of the present invention. In the driving phase among the multiple phases, the control module 480 may set the respective state (or the respective logical values) of the control signals CONTROL1 and CONTROL2 according to the classification result of the second sample, and control the PMICs 410 and 420 with the control signals CONTROL1 and CONTROL2 to set the driving voltages PWR1 and PWR2, respectively, where the UFS version detection signal UFS_VERSION_DETECTION (e.g., UFS_VERSION_DETECTION=V_{TEST}) may indicate the classification result of the second sample, such as the classification result of whether the second sample belongs to the UFS v2 samples or the UFS v3, v4 or newer version samples, so the control module 480 may set the respective state (or the respective logical values) of the control signals CONTROL1 and CONTROL2 according to the UFS version detection signal UFS_VERSION_DETECTION, to provide the driving voltages corresponding to the classification result.

When UFS_VERSION_DETECTION =V_{TEST}, indicating that the second sample belongs to the UFS v2 samples, the control module 480 may set the respective state of the control signals CONTROL1 and CONTROL2 according to the UFS version detection signal UFS_VERSION_DETECTION in order to set the voltage level of the driving voltage PWR1 (or “the PWR1 level”) and the voltage level of the driving voltage PWR2 (or “the PWR2 level”), respectively, for controlling the PMICs 410 and 420 to provide the driving voltages VCCQ2 and VCC corresponding to the classification result, where VCCQ2=1.8 V and VCC=3.3 V.

According to some embodiments, the program code 52C stored in the computer-readable medium 52M may cause the host device 50 (e.g., the processor 52) to operate according to the method when executed by the host device 50 (e.g., the processor 52), and the associated operations of the method may comprise:
(1) in the testing phase, the host device 50 (or the control module 480 therein such as the processor 52) may utilize any of the aforementioned PMICs such as the PMIC 410 to output any of the aforementioned voltages PWR such as the driving voltage PWR1 to be the testing voltage V_{TEST}, where PWR=1.2V;
(2) in the testing phase, the host device 50 (or the control module 480 therein such as the processor 52) may determine whether the voltage level of the UFS version detection signal UFS_VERSION_DETECTION is a default voltage level (e.g., a ground level) indicating a default logical value (e.g., the logical value 0) or a first voltage level (e.g., a power level) indicating a first logical value (e.g., the logical value 1);
(3) when detecting that the voltage level of the UFS version detection signal UFS_VERSION_DETECTION is the first voltage level (e.g., the power level such as a high level) indicating the first logical value (e.g., the logical value 1), the host device 50 (or the control module 480 therein such as the processor 52) may change any of the aforementioned voltages PWR such as the driving voltage PWR1 to 1.8 V for being used in the driving phase;
(4) when detecting that the voltage level of the UFS version detection signal UFS_VERSION_DETECTION is the default voltage level (e.g., the ground level such as a lower level) indicating the default logical value (e.g., the logical value 0), the host device 50 (or the control module 480 therein such as the processor 52) may maintain any of the aforementioned voltages PWR such as the driving voltage PWR1 at 1.2 V for being used in the driving phase; and
(5) the host device 50 (or the control module 480 therein such as the processor 52) may release the locking state of the host device 50, such as that of the SoC or the peripheral circuit system, and then boot the system of the host device 50, such as the system implemented with a main program module running on the processor 52;
but the present invention is not limited thereto. As long as the implementation of the present invention will not be hindered and no malfunction of the electronic device 10 (or the host device 50 and/or the memory device 100 therein) will occur, the associated operations may vary. For example, in a first control-module setup control scheme of the method, the control module 480 may be implemented by way of SoC or MCU, as well as firmware or software inside (e.g., the firmware or software running thereon), where the control module 480 may be configured to detect the detection signal (e.g., the UFS version detection signal UFS_VERSION_DETECTION) from the PCB 50B (e.g., the PCB 400) in the testing phase, and then the firmware (FW) or the software (SW) may decide to set the voltage level of the driving voltage PWR1 (e.g., the voltage output (Vout) of the PMIC 410) as 1.8 V or 1.2 V for being used in the driving phase. The architecture of the first control-module setup control scheme may be applied into any phone system or any embedded system if the system needs the UFS memory. In another example, in a second control-module setup control scheme of the method, the control module 480 may be implemented by way of the PMIC automatic control circuit (or “the PMIC auto-circuit”). As any embedded system among most of the embedded systems may boot from its UFS memory, it can use the second control-module setup control scheme (or the PMIC auto-circuit), to identify the UFS version detection signal UFS_VERSION_DETECTION as a switch/switching option. The system will set the expected voltage level as a booting result. In some examples, the control module 480 may be implemented by way of one or a combination of the PMIC(s), the SoC architecture, the PMIC auto-circuit, the ROM code, etc.

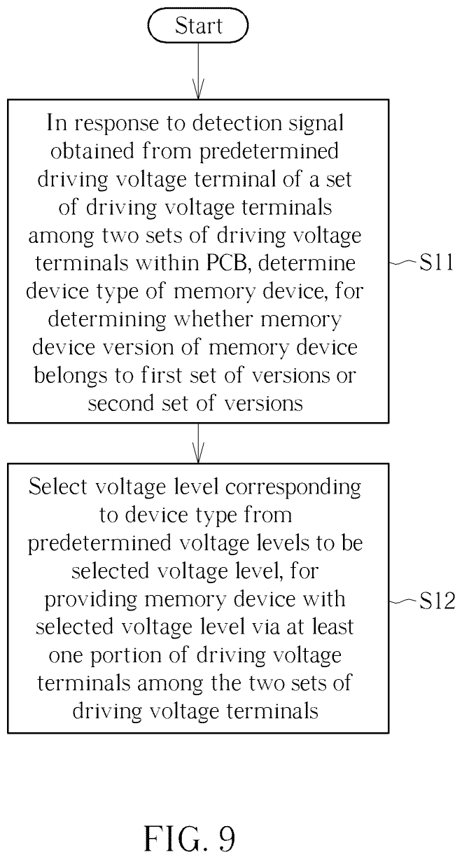

FIG. 9 illustrates a working flow of the method according to an embodiment of the present invention. The host device 50 (or the control module 480 therein such as the processor 52) can operate according to the method to perform the working flow shown in FIG. 9, and more particularly, can operate based on at least one control scheme (e.g., one or more control schemes) of the method, such as the universal board system control scheme, the terminal reuse/redefinition control scheme, the driving voltage control scheme, etc.

In Step S11, during the testing phase, in response to the detection signal (e.g., the UFS version detection signal UFS_VERSION_DETECTION) obtained from the predetermined driving voltage terminal of the set of driving voltage terminals among the two sets of driving voltage terminals within the PCB 50B (e.g., the PCB 400), the host device 50 (or the control module 480 therein such as the processor 52) can determine the device type of the memory device 100, for determining whether the memory device version of the memory device 100 belongs to the first set of versions or the second set of versions.

In Step S12, during the driving phase, the host device 50 (or the control module 480 therein such as the processor 52) can select the voltage level corresponding to the device type from the multiple predetermined voltage levels to be the selected voltage level, for providing the memory device 100 with the selected voltage level via the aforementioned at least one portion of driving voltage terminals among the two sets of driving voltage terminals.

The memory device 100 may represent the UFS device. Taking the architecture shown in any figure among FIG. 4 to FIG. 8 as an example, the two sets of driving voltage terminals may comprise a set of VCCQ driving voltage terminals such as the set of VCCQ terminals 451 and a set of VCCQ2 driving voltage terminals such as the set of VCCQ2 terminals 452. For example, the set of driving voltage terminals and another set of driving voltage terminals among the two sets of driving voltage terminals may represent the set of VCCQ2 driving voltage terminals and the set of VCCQ driving voltage terminals, respectively. In addition, all terminals within (or on) the PCB 50B (e.g., the PCB 400) that are arranged for installing the memory device 100 may conform to the ball-out definitions specified by multiple versions of the UFS specification, where the multiple versions may at least comprise the second version (or “the v2”), the third version (or “the v3”), and the fourth version (or “the v4”). More particularly, in addition to the second, the third, and the fourth versions (i.e., the v2, the v3, and the v4), the multiple versions may further comprise at least one subsequent version (or the newer version). For brevity, similar descriptions for this embodiment are not repeated in detail here.

For better comprehension, the method may be illustrated with the working flow shown in FIG. 9, but the present invention is not limited thereto. According to some embodiments, one or more steps may be added, deleted, or changed in the working flow shown in FIG. 9. For example, the set of driving voltage terminals and the other set of driving voltage terminals among the two sets of driving voltage terminals may represent a set of second driving voltage terminals such as the set of VCCQ2 driving voltage terminals and a set of first driving voltage terminals such as the set of VCCQ driving voltage terminals, respectively. During the testing phase, the host device 50 (or the control module 480 therein such as the processor 52) can utilize a first PMIC (e.g., the PMIC 410) to output a first voltage having a predetermined voltage level, such as the driving voltage VCCQ having the predetermined voltage level of 1.2V, to be the testing voltage V_{TEST}, and can utilize the second driving voltage terminals among the set of second driving voltage terminals except the predetermined driving voltage terminal and all first driving voltage terminals among the set of first driving voltage terminals to receive the testing voltage V_{TEST}, in order to obtain the detection signal such as the UFS version detection signal UFS_VERSION_DETECTION from the predetermined driving voltage terminal. In addition, the memory device 100 can be implemented via at least one die and the package thereof (e.g., the die 501 and the package 500 thereof in the architecture shown in FIG. 5, or the die 601 and the package 600 thereof in the architecture shown in FIG. 6). Regarding a first driving voltage and a second driving voltage respectively corresponding to the set of first driving voltage terminals and the set of second driving voltage terminals, such as the driving voltages VCCQ and VCCQ2 respectively corresponding to the set of VCCQ driving voltage terminals and the set of VCCQ2 driving voltage terminals, the wire bonding of the aforementioned at least one die involves only one driving voltage (e.g., the driving voltage VCCQ in the architecture shown in FIG. 7, or the driving voltage VCCQ2 in the architecture shown in FIG. 8) among the first and the second driving voltages, in order to save the associated costs. For brevity, similar descriptions for these embodiments are not repeated in detail here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for performing device type detection of a memory device with aid of driving voltage path detection, the memory device being installed on a printed circuit board (PCB) of a host device, the memory device comprising a memory controller and a non-volatile (NV) memory, the NV memory comprising at least one NV memory element, the method comprising:
in response to a detection signal obtained from a predetermined driving voltage terminal of a set of driving voltage terminals among two sets of driving voltage terminals within the PCB, determining a device type of the memory device, for determining whether a memory device version of the memory device belongs to a first set of versions or a second set of versions; and
selecting a voltage level corresponding to the device type from multiple predetermined voltage levels to be a selected voltage level, for providing the memory device with the selected voltage level via at least one portion of driving voltage terminals among the two sets of driving voltage terminals.

2. The method of claim 1, wherein the memory device represents a Universal Flash Storage (UFS) device.

3. The method of claim 2, wherein the two sets of driving voltage terminals comprise a set of VCCQ driving voltage terminals and a set of VCCQ2 driving voltage terminals.

4. The method of claim 3, wherein the set of driving voltage terminals and another set of driving voltage terminals among the two sets of driving voltage terminals represent the set of VCCQ2 driving voltage terminals and the set of VCCQ driving voltage terminals, respectively.

5. The method of claim 1, wherein all terminals within the PCB that are arranged for installing the memory device conform to ball-out definitions specified by multiple versions of Universal Flash Storage (UFS) specification, wherein the multiple versions at least comprise a second version, a third version, and a fourth version.

6. The method of claim 5, wherein in addition to the second, the third, and the fourth versions, the multiple versions further comprise at least one subsequent version.

7. The method of claim 1, wherein multiple phases of the host device comprise a testing phase and a driving phase; and in response to the detection signal obtained from the predetermined driving voltage terminal of the set of driving voltage terminals among the two sets of driving voltage terminals within the PCB, determining the device type of the memory device, for determining whether the memory device version of the memory device belongs to the first set of versions or the second set of versions further comprises:
during the testing phase, in response to the detection signal obtained from the predetermined driving voltage terminal of the set of driving voltage terminals among the two sets of driving voltage terminals within the PCB, determining the device type of the memory device, for determining whether the memory device version of the memory device belongs to the first set of versions or the second set of versions; and
wherein selecting the voltage level corresponding to the device type from the multiple predetermined voltage levels to be the selected voltage level, for providing the memory device with the selected voltage level via the at least one portion of driving voltage terminals among the two sets of driving voltage terminals further comprises:
during the driving phase, selecting the voltage level corresponding to the device type from the multiple predetermined voltage levels to be the selected voltage level, for providing the memory device with the selected voltage level via the at least one portion of driving voltage terminals among the two sets of driving voltage terminals.

8. The method of claim 7, wherein the set of driving voltage terminals and another set of driving voltage terminals among the two sets of driving voltage terminals represent a set of second driving voltage terminals and a set of first driving voltage terminals, respectively; and the method further comprises:
during the testing phase, utilizing a first power management integrated circuit (PMIC) to output a first voltage having a predetermined voltage level to be a testing voltage; and
during the testing phase, utilizing second driving voltage terminals among the set of second driving voltage terminals except the predetermined driving voltage terminal and all first driving voltage terminals among the set of first driving voltage terminals to receive the testing voltage, in order to obtain the detection signal from the predetermined driving voltage terminal.

9. The method of claim 1, wherein the memory device is implemented via at least one die and a package thereof; the set of driving voltage terminals and another set of driving voltage terminals among the two sets of driving voltage terminals represent a set of second driving voltage terminals and a set of first driving voltage terminals, respectively;
and regarding a first driving voltage and a second driving voltage respectively corresponding to the set of first driving voltage terminals and the set of second driving voltage terminals, wire bonding of the at least one die is involved with only one driving voltage among the first and the second driving voltages, in order to save costs.

10. A host device that operates according to the method of claim 1.

11. A computer-readable medium storing a program code which causes the host device to operate according to the method of claim 1 when executed by the host device.

12. A printed circuit board (PCB) for performing device type detection of a memory device with aid of driving voltage path detection, the memory device being installed on the PCB of a host device, the PCB comprising:
a control module, arranged to control operations of the PCB, wherein the control module comprises at least one circuit; and
at least one power management integrated circuit (PMIC), coupled to the control module, arranged to perform power management under control of the control module, for selectively providing at least one driving voltage to the memory device to be power for the memory device;
wherein:
in response to a detection signal obtained from a predetermined driving voltage terminal of a set of driving voltage terminals among two sets of driving voltage terminals within the PCB, the control module determines a device type of the memory device, for determining whether a memory device version of the memory device belongs to a first set of versions or a second set of versions; and
the control module selects a voltage level corresponding to the device type from multiple predetermined voltage levels to be a selected voltage level, for providing the memory device with the selected voltage level via at least one portion of driving voltage terminals among the two sets of driving voltage terminals.
